(19) United States
(12) Patent Application Publication
(10) Pub. No.: US 2010/0255622 A1
(43) Pub. Date: Oct. 7, 2010

(54) SYSTEMS AND METHODS FOR AFFIXING A SILICON DEVICE TO A SUPPORT STRUCTURE

(75) Inventor: Mark Eskridge, Renton, WA (US)

Correspondence Address: HONEYWELL/BLG;Patent Services, 101 Columbia Road, PO Box 2245, Morristown, NJ, 07962-2245, US

(73) Assignee: Honeywell International, Inc., Morristown, NJ (US)

(21) Appl. No.: 12/418,871

(22) Filed: Apr. 6, 2009

(51) Int. Cl. H01L 21/50

(52) U.S. Cl. 438/51; 257/E21.499

(57) ABSTRACT

Methods of affixing a device to a support structure are disclosed. In an embodiment, the device includes a face on which is disposed at least one electrical connector. The method includes forming a ribbon suspender having a width, a first connection portion, a second connection portion, and a support portion coupling the first connection portion to the second connection portion. The support portion defines an apex portion of the ribbon suspender. The apex portion is bonded to the device. The first and second connection portions of the ribbon suspender are bonded to the support structure. The support portion of the ribbon suspender flexes to accommodate acceleration of the support structure.

### BACKGROUND OF THE INVENTION

Semiconductor device dies are affixed into device packages for protection and for more convenient installation into an end use device. Device packages may be made of any suitable sturdy and resilient material, such as ceramic, glass, or plastic. The semiconductor device die is affixed to its package in a variety of manners, including the use of epoxy, solder, or brazing.

Various semiconductor-based devices are configured to detect physical events and/or cause physical events. Such devices are generally known as a Micro-Electro-Mechanical Systems (MEMS) device. For example, a MEMS gyroscope may be used to determine angular rotation and a MEMS accelerometer may be used to sense linear acceleration. The MEMS gyroscope and accelerometer measure rotation and acceleration, respectively, by measuring movement and/or forces induced in one or more silicon proof masses mechanically coupled to and suspended from a substrate, typically glass, using one or more silicon flexures. As another example, a MEMS motor may be used to induce or sense movement in a rotor.

A number of recesses etched into the substrate of the MEMS device allow selective portions of the silicon structure to move back and forth freely within an interior portion of the MEMS device. A pattern of electrical connectors, also known as metal traces, are formed on the MEMS device substrate to deliver various electrical voltages and signal outputs to and/or from the MEMS device. The MEMS device, after fabrication, may be affixed to a support structure, such as a device package, with electrical connection of the MEMS device bonded to corresponding electrical connections of the support structure.

For example, the support structure may have wire leads or connectors that provide connectivity between the outside surface of the support structure and the metal traces of the MEMS device. A flip chip bonding process affixes the MEMS die to its support structure while bonding of the metal traces of the MEMS device with the wire leads or connectors of the support structure.

FIG. 1 illustrates a cross sectional view of a conventional die/package assembly. A die 10 is attached to a surface of a support structure (e.g., board or package) 20. The die 10 is electrically connected to the support structure 20 by electrically conductive ribbon bonds 30. Typically, the ribbons 30 provide only an electrical (and possibly thermal) path from the die 10 to the support structure 20.

Another type of support structure is a leadless chip carrier. After the MEMS die is affixed to the leadless chip carrier, external wire bonds are made to electrically couple connections of the MEMS device with traces on the leadless chip carrier or with connectors to other electrical devices.

MEMS devices may be very sensitive to inducted stresses and/or changes in orientation of the MEMS device components. Very small changes in stress and/or orientation of the working components of the MEMS device may significantly change the signal output of the MEMS device. Accordingly, prior to use in the field, the MEMS device is calibrated. Typically, calibration of the MEMS device is performed at the factory or during a field calibration process. For example, output of a stationary MEMS gyroscope or accelerometer should be null (zero). Accordingly, during the MEMS device calibration process, the output of the stationary MEMS gyroscope and accelerometer is referenced to a null value and/or is electrically compensated to a null output.

Such “hard mounting” of the MEMS die to the support structure results in the MEMS die becoming solidly, or rigidly, affixed to the support structure. Temperature fluctuations of the device package and/or the MEMS causes thermal expansion (during heating) and/or contraction (during cooling) in the support structure. However, since the materials of the device package, the MEMS die, and any bonding material therebetween, are different, the relative amount of expansion and/or retraction will be different for the support structure, the MEMS die, and any bonding material therebetween. This differential expansion and/or differential contraction during a temperature change may induce changes in the orientation and/or stress of the working components of the MEMS device. Such differential expansion and/or differential contraction during a temperature change may result in the MEMS device becoming uncalibrated.

Further, some materials do not return to their original size and/or shape after a temperature cycle. For example, a gold ball bond may be used to affix the MEMS die to the support structure. Because of the ductility of the gold ball bond, a temperature-induced deformation causes a nonelastic deformation of the gold ball bond. Accordingly, after a number of temperature cycles, the gold ball bond does not return to its original pre-deformation form and/or stress. Such nonelastic, hysteresis deformation of the gold ball bond may result in the MEMS device becoming uncalibrated.

Accordingly, it is desirable to isolate the MEMS die from changes in orientation and/or stress that may occur as a result of differential expansion and/or differential contraction during a temperature change, and from hysteresis deformations resulting from temperature cycles. One prior art technique is to dispose an isolating structure between the MEMS die and the device package. For example, a plate, a pad, or the like made of a relatively thermal-expansion-resistant material may be bonded to the MEMS die and the device package. However, such intermediate isolating structures may not be entirely effective as movement and or stresses may be transferred through the isolating structure to the MEMS die. Further, such intermediate isolating structures may be relatively complex and expensive to fabricate and install between the MEMS die and the device package.

### SUMMARY OF THE INVENTION

Systems and methods of affixing a silicon device to a support structure using ribbon suspenders are disclosed. In an embodiment, the device includes a face on which is disposed at least one electrical connector. A method includes forming a ribbon suspender having a width, a first connection portion, a second connection portion, and a support portion coupling the first connection portion to the second connection portion. The support portion defines an apex portion of the ribbon suspender. The apex portion is bonded to the device. The first and second connection portions of the ribbon suspender are bonded to the support structure. The support portion of the ribbon suspender flexes to accommodate acceleration of the support structure.

### BRIEF DESCRIPTION OF THE DRAWINGS

Preferred and alternative embodiments are described in detail below with reference to the following drawings:

FIG. 1 illustrates a conventional die/package assembly;

FIG. 2 illustrates an exemplary ribbon suspender embodiment;

FIG. 3 illustrates a side view of a plurality of electrically conductive ribbon suspenders affixing a MEMS die to a support structure according to an embodiment;

FIG. 4 illustrates formation of a ribbon suspender by the tool of FIG. 9;

FIG. 5 illustrates a side view of a plurality of electrically conductive ribbon suspenders affixing a MEMS die to a support structure according to an alternative embodiment;

FIG. 6 illustrates a bonding approach used to form the device of FIG. 5 according to an embodiment;

FIG. 7 illustrates a side view of a plurality of electrically conductive ribbon suspenders affixing a MEMS die to a support structure according to an alternative embodiment;

FIG. 8 illustrates a bonding approach used to form the device of FIG. 7 according to an embodiment;

FIG. 9 illustrates an exemplary tool that forms the ribbon suspender; and

FIG. 10 illustrates a side view of a plurality of electrically conductive ribbon suspenders affixing a MEMS die to a support structure according to an alternative embodiment.

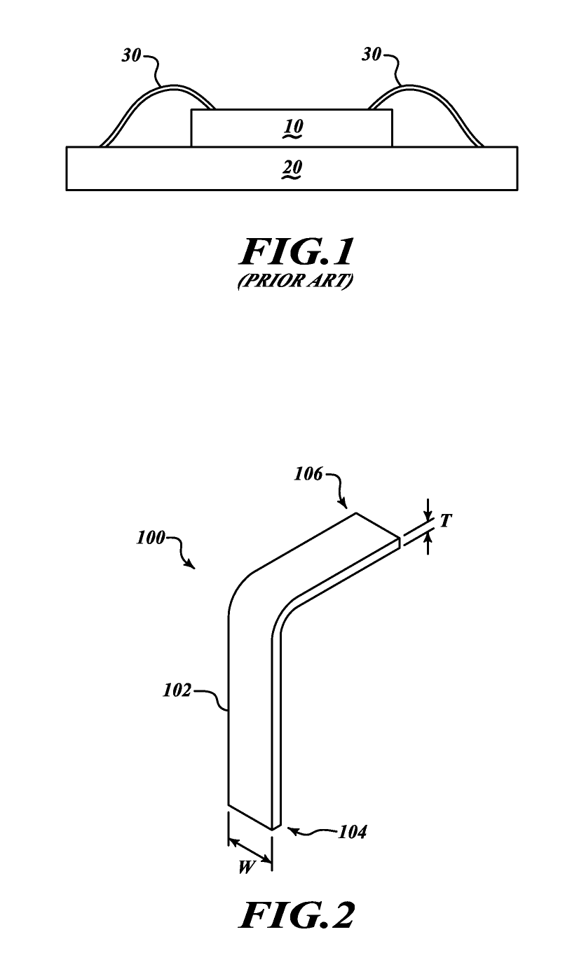

### DETAILED DESCRIPTION OF THE PREFERRED EMBODIMENT

Embodiments of the invention may incorporate, or otherwise utilize, concepts described in commonly owned U.S. patent application Ser. No. 12/340,133 entitled “SYSTEMS AND METHODS FOR AFFIXING A SILICON DEVICE TO A SUPPORT STRUCTURE,” which is hereby incorporated by reference as if fully set forth herein.

FIG. 2 illustrates an exemplary ribbon suspender 100 embodiment. The ribbon suspender 100 comprises a support portion 102 for affixing the ribbon suspender to a silicon device, such as, but not limited to, a Micro-Electro-Mechanical Systems (MEMS) die. The ribbon suspender 100 further includes a first connection portion 104 and a second connection portion 106 for affixing the ribbon suspender 100 to a support structure.

The ribbon suspender 100 is formed from a ribbon of bonding material, which may include aluminum, gold, platinum and/or a gold-plated metal. The ribbon suspender 100 is defined by a thickness “T” and a width “W” (that may be greater than the thickness). The width and thickness of the ribbon suspender 100 define the flexure characteristics and suspension characteristics of the ribbon suspender 100. Accordingly, the ribbon suspender 100 may be configured to isolate a MEMS die from accelerations, changes in orientation and/or stress associated with a support structure, which may occur as a result of differential expansion and/or differential contraction during a temperature change, and from hysteresis deformations resulting from temperature cycles.

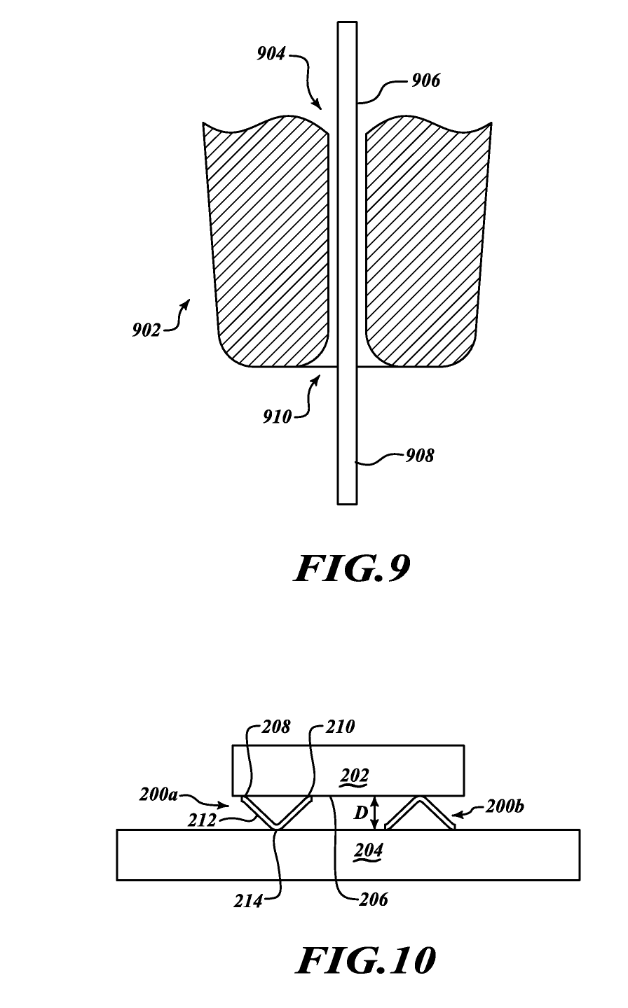

FIG. 9 illustrates an exemplary tool 902, which may be formed from ceramic, metal or other suitable material, that is operable to form a ribbon suspender 100. The tool 902 has a capillary 904, generally shaped in accordance with the width and thickness of a ribbon 906 from which a ribbon suspender 100 is formed. A roll of the ribbon 906 is unwound such that a portion 908 of the ribbon 906 is extended outwardly from a lower end 910 of the tool 902. By appropriate manipulation of the lower end 910 of the tool 902, the portion 908 of the ribbon 906 may be formed in a desired shape. For example, the lower end 910 of the tool 902 may be moved so that the portion 908 of the ribbon 906 is bent, thereby forming, for example, the support portion 102 (and associated apex portion, described in greater detail below herein) between the first connection portion 104 and the second connection portion 106.

FIG. 4 illustrates in greater detail the formation of a ribbon suspender 100 by the tool 902, according to an embodiment. In a step A, the ribbon 906 is fed to the tool 902. The ribbon 906 is shown entering the capillary 904 of the bonding tool 902. In step A, a clamp 912 is applied to the ribbon 906, so that when the tool 902 is moved, the ribbon moves with the tool.

In a step B, the lower end 910 is moved down to a first bonding location 410 of a bonding surface 400, and a combination of heat, pressure, and/or ultrasonic energy is applied by the tool 902, or other device, as necessary to bond the ribbon 906 to the first bonding location. The clamp 912 may then be released.

As illustrated in a step C, the bonding tool 902 is free to move relative to the ribbon 906, which remains bonded to the first bonding location 410. In steps C through D, the shape of the lower end 910 and the path taken by the tool 902 relative to the ribbon 906 form a desired ribbon-suspender 100 shape.

In step D, clamp 912 is again applied to the ribbon 906, the lower end 910 is moved down to a second bonding location 420, and a combination of heat, pressure, and/or ultrasonic energy is applied by the tool 902, or other device, as necessary to bond the ribbon to the second bonding location. As illustrated in a step E, this action may also thin and weaken an area of the ribbon 906 proximal to the second bonding location 420, allowing the bonding tool 902 and ribbon to be pulled away from the bonding surface 400, breaking the ribbon next to the second bonding location 420 to form the ribbon suspender 100. The bonding tool 902 is now ready to repeat the above-described process.

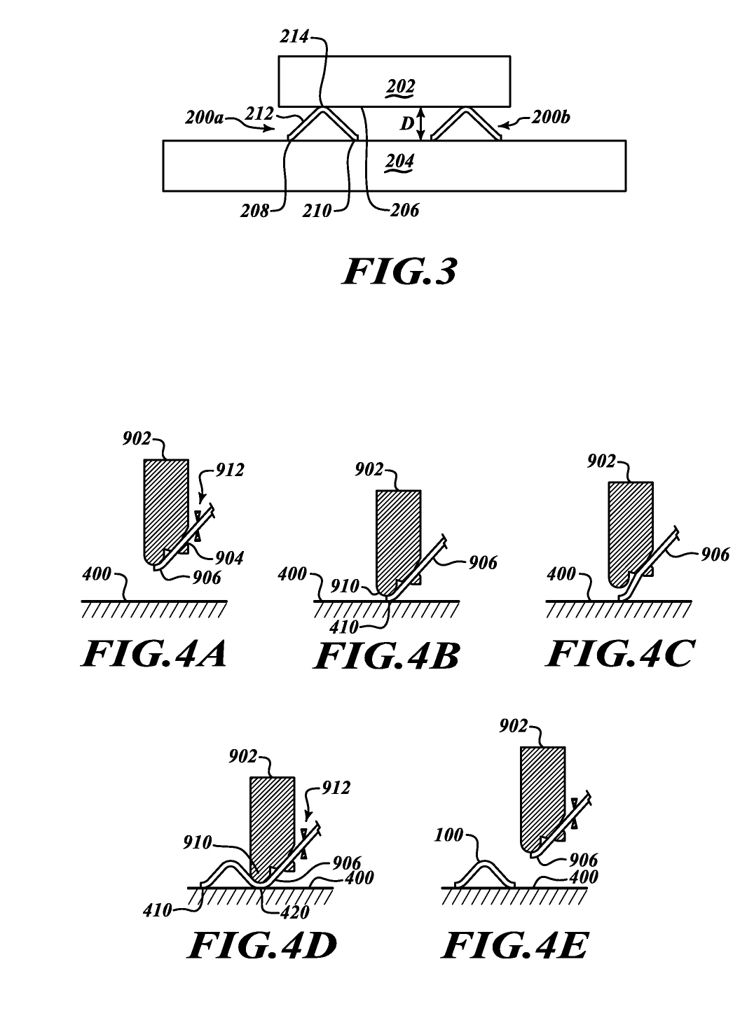

FIG. 3 illustrates a side view of a plurality of electrically conductive ribbon suspenders 200a and 200b, similar or identical in configuration to the ribbon suspender 100 illustrated in FIG. 2, affixing a MEMS die 202 to a support structure 204 according to an embodiment. For purposes of brevity and clarity, only the structure and functionality of ribbon suspender 200a will be discussed in detail; it is to be understood that such discussion similarly applies to ribbon suspender 200b and additional similar ribbon suspenders (not shown) that can be similarly employed in alternative embodiments. The die 202 includes a face 206 on which is disposed at least one electrical connector (not shown) operable to provide electrical signals to, and receive electrical signals from, the support structure 204. The support structure 204 may be any suitable structure that the MEMS die 202 can be affixed to. For example, the support structure 204 may be a device package in which the MEMS die 202 is affixed. Another non-limiting example of the support structure 204 is a printed circuit board or the like having a plurality of devices affixed thereon.

As alluded to with reference to FIG. 2, the ribbon suspender 200a includes first and second connection portions 208, 210, and a support portion 212 coupling the first connection portion to the second connection portion. The support portion 212 defines an apex portion 214 of the ribbon suspender 200a. In the illustrated embodiment, the apex portion 214 is bonded to the electrical connector of the face 206, and the first and second connection portions 208, 210 are bonded to the support structure 204. Consequently, the support portion 212 flexes to accommodate acceleration, as well as expansion or contraction, of the support structure 204. In an embodiment, the ribbon suspender 200a is configured such that, when the ribbon suspender 200a is bonded to the die 202 and support structure 204, the distance D between the die 202 and the support structure 204 is greater than the width W illustrated in FIG. 2.

In an embodiment, the apex portions of the ribbon suspenders 200a, 200b are first bonded to the face 206 of the die 202. Subsequently, the respective connection portions (e.g., connection portions 208, 210 of ribbon suspender 200a) of the ribbon suspenders 200a, 200b are attached to the support structure 204. Each of the die 202, ribbon suspenders 200a, 200b, and support structure 204 may be so bonded to one another using, for example, a conductive epoxy or solder, or other appropriate bonding material.

In an alternative embodiment, illustrated in FIG. 10, the respective connection portions (e.g., connection portions 208, 210 of ribbon suspender 200a) of the ribbon suspenders 200a, 200b are first bonded to the face 206 of the die 202. Subsequently, the apex portions of the ribbon suspenders 200a, 200b are attached to the support structure 204. Each of the die 202, ribbon suspenders 200a, 200b, and support structure 204 may be so bonded to one another using, for example, a conductive epoxy or solder, or other appropriate bonding material.

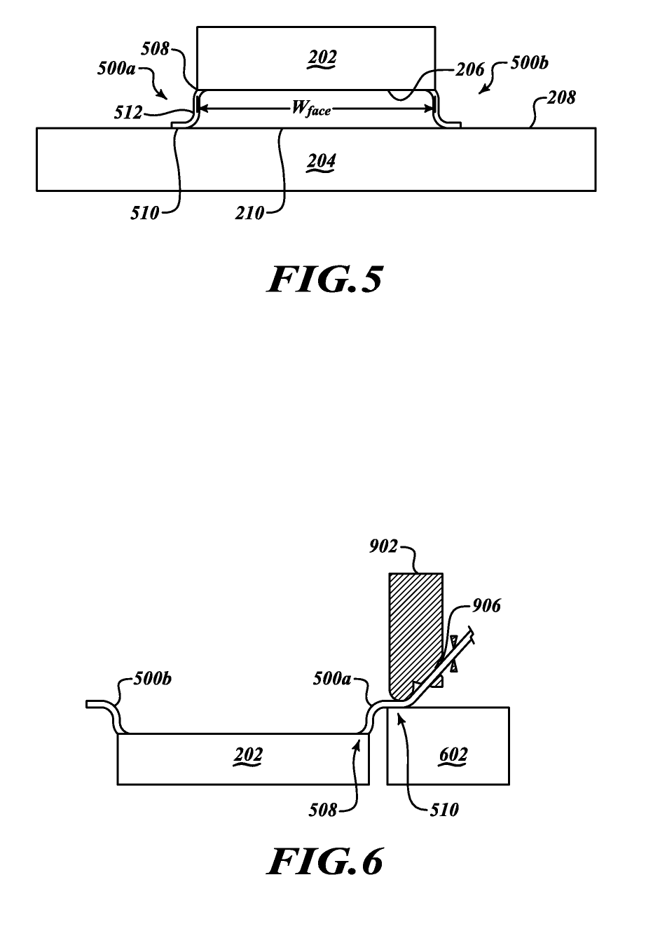

FIG. 5 illustrates a side view of a plurality of electrically conductive ribbon suspenders 500a and 500b affixing a MEMS die 202 to a support structure 204 according to an alternative embodiment. The ribbon suspenders 500a, 500b are configured in a manner similar to suspender 100, but resemble half of such a suspender in a generally “S”-shaped configuration. For purposes of brevity and clarity, only the structure and functionality of ribbon suspender 500a will be discussed in detail; it is to be understood that such discussion similarly applies to ribbon suspender 500b and additional similar ribbon suspenders (not shown) that can be similarly employed in alternative embodiments. The die 202 includes a face 206 on which is disposed at least one electrical connector (not shown) operable to provide electrical signals to, and receive electrical signals from, the support structure 204.

The ribbon suspender 500a includes a first connection portion 508, a second connection portion 51 0, and a support portion 512 coupling the first connection portion to the second connection portion. In the illustrated embodiment, the first connection portion 508 is bonded to the electrical connector of the face 206.

The face 206 has an area defined and bounded, at least in part, by a width (or diameter, depending on the geometric configuration of die 202) W_{face}. The second connection portion 510 is bonded to a surface 208 of the support structure 204 facing, or otherwise disposed toward, the face 206. The support-structure surface 208 includes a first region 210 directly below (or above, depending on the respective orientations of the die 202 and support structure 204) face 206. The area of the first region 210 is equal to the area of the face 206, and the first region is coaxial with the face.

In the illustrated embodiment, the second connection portion 510 is bonded to a region of the support-structure surface 208 external to the first region 210 (i.e., outside of the perimeter of the die 202). The support portion 512 flexes to accommodate acceleration, as well as expansion or contraction, of the support structure 204. In an embodiment, the ribbon suspender 500a is configured such that, when the ribbon suspender 500a is bonded to the die 202 and support structure 204, the distance between the die 202 and the support structure 204 (similar to the distance D illustrated in FIG. 3) is greater than the width W illustrated in FIG. 2.

In an embodiment, the first connection portions of the ribbon suspenders 500a, 500b are first bonded to the face 206 of the die 202. FIG. 6 illustrates such a bonding approach, similar or identical to the approach described with reference to FIG. 4, using tool 902. First, the tool 902 and ribbon 906 are used to create and bond to the die 202 the first connection portion 508. The second connection portion 510 is formed by applying the ribbon 906 to a surface 602, composed of, for non-limiting example, tungsten, that is bond-resistant. This application forms and breaks the ribbon 906, leaving the second connection portion 510 extended above the die 202, as is illustrated with reference to ribbon suspender 500b.

Subsequently, and referring back to FIG. 5, the second connection portions (e.g., connection portion 510 of ribbon suspender 500a) of the ribbon suspenders 500a, 500b are attached to the support structure 204. Each of the die 202, ribbon suspenders 500a, 500b, and support structure 204 may be so bonded to one another using, for example, a conductive epoxy or solder, or other appropriate bonding material.

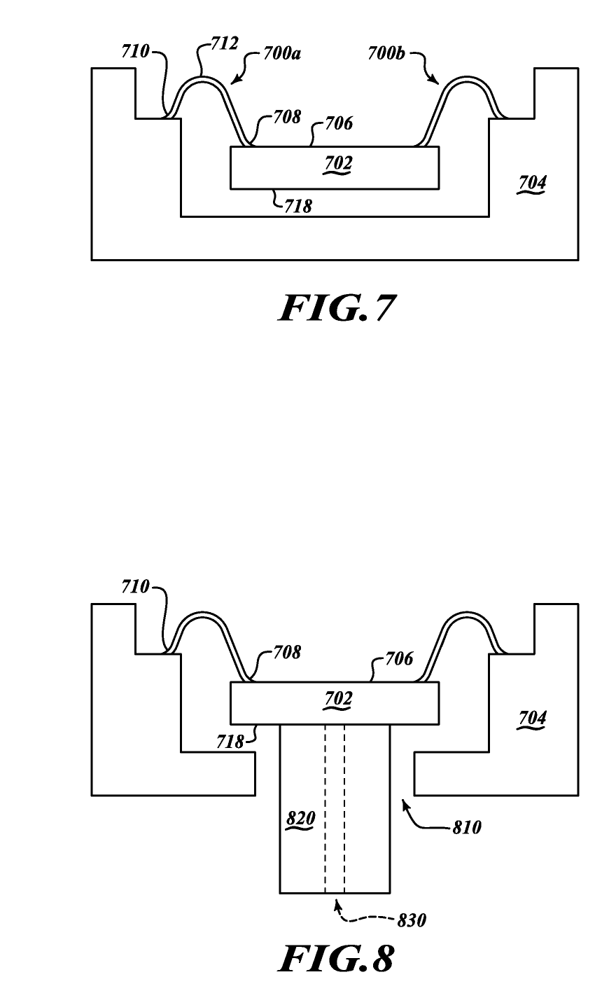

FIG. 7 illustrates a side view of a plurality of electrically conductive ribbon suspenders 700a and 700b, similar or identical in configuration to the ribbon suspender 100 illustrated in FIG. 2, affixing a MEMS die 702 to a support structure 704 according to an alternative embodiment. For purposes of brevity and clarity, only the structure and functionality of ribbon suspender 700a will be discussed in detail; it is to be understood that such discussion similarly applies to ribbon suspender 700b and additional similar ribbon suspenders (not shown) that can be similarly employed in alternative embodiments. The die 702 includes a face 706, on which is disposed at least one electrical connector (not shown) operable to provide electrical signals to, and receive electrical signals from, the support structure 704, and an opposing surface 718. The support structure 704 may be any suitable structure that the MEMS die 702 can be affixed to. For example, the support structure 704 may be a device package in which the MEMS die 702 is affixed. Another non-limiting example of the support structure 704 is a printed circuit board or the like having a plurality of devices affixed thereon.

As alluded to with reference to FIG. 2, the ribbon suspender 700a includes first and second connection portions 708, 710, and a support portion 712 coupling the first connection portion to the second connection portion. In the illustrated embodiment, the first connection portion 708 is bonded to the electrical connector of the face 706, and the second connection portion 710 is bonded to the support structure 704. Consequently, the support portion 712 flexes to accommodate acceleration, as well as expansion or contraction, of the support structure 704.

FIG. 8 illustrates an approach to bonding the die 702 to the support structure 704, according to an embodiment. In the illustrated approach, an orifice 810 may be etched or otherwise formed in the support structure 704, allowing the insertion therethrough of a stabilizing tool 820. The opposing surface 718 of the die 702 is made to engage a top surface of the stabilizing tool 820 such that the die and support structure 704 do not contact one another. Such engagement may be achieved through the use of suction that may be applied via a capillary 830 formed through the length of the tool 820. Subsequently, the first connection portion 708 is bonded to the face 706, and the second connection portion 710 is bonded to the support structure 704. After the first and second connection portions 708, 710 are so bonded, the stabilizing tool 820 is disengaged from the opposing surface 718 such that the die 702 and support structure 704 continue to not contact one another. The orifice 810 may then be filled or covered, as desired, to produce the configuration illustrated in FIG. 7. As alternatives to the tool 820, the die 702 may be supported during bonding using clamps, removable supports, or a dissolvable material.

Embodiments of the ribbon suspender 100 were described and illustrated as having the same, or substantially the same, width and thickness as the other ribbon suspenders 100. Differently dimensioned ribbon suspenders 100 may be used to affix the MEMS die 202, 702 and the support structure 204, 704 based upon the design needs of a particular application. For example, a wider width ribbon suspender 100 may be used to provide additional support, and/or flexure to accommodate greater amounts of thermal expansion or thermal contraction. Additionally, a wider ribbon suspender 100 will provide a greater resistance to torque forces or stresses. Also, a thicker ribbon suspender 100 will have a lesser degree of flexure in the support portion 102.

In the various embodiments, the ribbon suspender 100 is made of a relatively resilient material, such as, but not limited to, a metal. An exemplary embodiment employs a ribbon material made of gold plated Kovar. Kovar is a trademarked nickel-cobalt ferrous alloy designed to be compatible with the thermal expansion characteristics of borosilicate glass (˜5×10⁻⁶/K between 30 and 200° C., to ˜10×10⁻⁶/K at 800° C.). Kovar allows direct mechanical connections over a range of temperatures with minimal thermal expansion. The optional gold plating of the Kovar facilitates mechanical bonding of the ribbon suspender 100 to the MEMS die 202, 702 and the support structure 204, 704. Other metals may be used.

While the preferred embodiment of the invention has been illustrated and described, as noted above, many changes can be made without departing from the spirit and scope of the invention. Accordingly, the scope of the invention is not limited by the disclosure of the preferred embodiment. Instead, the invention should be determined entirely by reference to the claims that follow.

The embodiments of the invention in which an exclusive property or privilege is claimed are defined as follows:

1. A method of affixing a device to a support structure, the device including a face on which is disposed at least one electrical connector, the method comprising:
forming a ribbon suspender comprising a first connection portion, a second connection portion, and a support portion coupling the first connection portion to the second connection portion, the support portion defining an apex portion of the ribbon suspender, the ribbon suspender having a width;
bonding the apex portion to the support structure; and
bonding the first and second connection portions of the ribbon suspender to the device,
wherein the support portion of the ribbon suspender flexes to accommodate acceleration of the support structure.

2. The method of claim 1, wherein bonding the first and second connection portions comprises bonding the first and second connection portions to the device face.

3. The method of claim 1, wherein the ribbon suspender is configured such that, when the ribbon suspender is bonded to the device and support structure, the distance between the device and the support structure is greater than the width.

4. The method of claim 1, wherein the ribbon suspender is a first ribbon suspender, and further comprising:
forming a second ribbon suspender comprising a third connection portion, a fourth connection portion, and a second support portion coupling the third connection portion to the fourth connection portion, the second support portion defining an apex portion of the second ribbon suspender, the second ribbon suspender having a second width;
bonding the apex portion of the second ribbon suspender to the support structure; and
bonding the third and fourth connection portions of the second ribbon suspender to the device,
wherein the support portion of the second ribbon suspender flexes to accommodate acceleration of the support structure.

5. The method of claim 2, wherein the ribbon suspender is electrically conductive and is configured to provide electrical communication between the face and the support structure.

6. The method of claim 1, wherein the first and second connection portions of the ribbon suspender are bonded to the device prior to the apex portion being bonded to the support structure.

7. A method of affixing a device to a support structure, the device including a face on which is disposed at least one electrical connector, the method comprising:
forming a ribbon suspender comprising a first connection portion, a second connection portion, and a support portion coupling the first connection portion to the second connection portion, the ribbon suspender having a width;
bonding the first connection portion of the ribbon suspender to a first surface of the device, the first surface having a first area; and
bonding the second connection portion of the ribbon suspender to a surface of the support structure, the support-structure surface facing the first surface of the device, the support-structure surface including a first region and a second region exclusive of the first region, the first region being coaxial with the first surface of the device, the first region having a second area equal to the first area,
wherein the second connection portion is bonded to the second region of the support-structure surface, the support portion of the ribbon suspender flexing to accommodate acceleration of the support structure.

8. The method of claim 7, wherein the first surface of the device comprises the device face.

9. The method of claim 7, wherein the ribbon suspender is configured such that, when the ribbon suspender is bonded to the device and support structure, the distance between the device and the support structure is greater than the width.

10. The method of claim 7, wherein the ribbon suspender is a first ribbon suspender, and further comprising:
forming a second ribbon suspender comprising a third connection portion, a fourth connection portion, and a second support portion coupling the third connection portion to the fourth connection portion, the second ribbon suspender having a second width;
bonding the third connection portion of the second ribbon suspender to the device first surface; and
bonding the fourth connection portion of the second ribbon suspender to the surface of the support structure,
wherein the fourth connection portion is bonded to the second region of the support-structure surface, the support portion of the second ribbon suspender flexing to accommodate acceleration of the support structure.

11. The method of claim 8, wherein the ribbon suspender is electrically conductive and is configured to provide electrical communication between the face and the support structure.

12. The method of claim 7, wherein the first connection portion is bonded to the device prior to the second connection portion of the ribbon suspender being bonded to the support-structure surface.

13. A method of affixing a device having first and second opposing surfaces to a support structure, the device including a face on which is disposed at least one electrical connector, the method comprising:
engaging the first opposing surface against a first surface of a stabilizing tool, the device being engaged such that the device and support structure do not contact one another;
forming a ribbon suspender comprising a first connection portion, a second connection portion, and a support portion coupling the first connection portion to the second connection portion;
bonding the first connection portion to the second opposing surface;
bonding the second connection portion to the support structure; and
after bonding the first connection portion to the second opposing surface and the second connection portion to the support structure, disengaging the stabilizing tool from the first opposing surface,
wherein the support portion of the ribbon suspender flexes to accommodate acceleration of the support structure.

14. The method of claim 13, wherein engaging the first opposing surface against the first surface of the stabilizing tool comprises applying, via the stabilizing tool, suction to the first opposing surface.

15. The method of claim 13, wherein the second opposing surface comprises the device face.

16. The method of claim 13, wherein the ribbon suspender is a first ribbon suspender, and further comprising:
forming a second ribbon suspender comprising a third connection portion, a fourth connection portion, and a second support portion coupling the third connection portion to the fourth connection portion;
bonding the third connection portion of the second ribbon suspender to the second opposing surface; and
bonding the fourth connection portion of the second ribbon suspender to the support structure,
wherein the support portion of the second ribbon suspender flexes to accommodate acceleration of the support structure.

17. The method of claim 15, wherein the ribbon suspender is electrically conductive and is configured to provide electrical communication between the face and the support structure.
